(19) United States
(12) Patent Application Publication
(10) Pub. No.: US 2004/0120129 A1
(43) Pub. Date: Jun. 24, 2004

(54) Multi-layer laminated structures for mounting electrical devices and method for fabricating such structures

(76) Inventors: Louis Soto, Warwick, RI (US); Gordon Monks, Francestown, NJ (US)

Correspondence Address: MERCHANT & GOULD PC, P.O. BOX 2903, MINNEAPOLIS, MN, 55402-0903, US

(21) Appl. No.: 10/329,324

(22) Filed: Dec. 24, 2002

(51) Int. Cl. H05K 1/11

(52) U.S. Cl. 361/795

(57) ABSTRACT

A multi-layer laminate on which electrical devices may be mounted includes a printed circuit portion, a first electrically isolating layer and a substantially rigid base. The printed circuit portion has a first major surface to receive one or more electrical devices to be mounted on the multi-layer laminate, and further has an electrically conductive layer having one or more conductive traces to be electrically connected to one or more of the electrical devices to be mounted on the multi-layer laminate. The laminate further includes at least one adhesive layer comprising an adhesive that is activatable at a first set of processing conditions, and re-activatable at a second set of processing conditions.

### TECHNICAL FIELD

This invention relates to structures for mounting electrical devices, and more particularly, to multi-layer laminated structures for mounting such devices, and to methods for fabricating such structures.

### RELATED ART

Electrical devices generate heat as they operate. This heat must usually be removed, one way or another, from the devices in order to keep the temperature of the devices within safe operating limits. As a result, the ability to remove and/or “manage” such heat is often essential to meeting the demand for electrical systems having smaller packages and higher performance (e.g., higher power), which in turn requires such systems to operate at ever increasing power densities.

Electrical devices are frequently mounted on a multi-layer laminated structure, which in turn is often mounted to a chassis or heat sink. This means that the laminated structure is in the thermal path between the electrical devices and the chassis or heatsink. Consequently, the ability to remove heat from the electrical devices often depends at least in part on the thermal conductivity of the laminated structure on which the devices are mounted. A high thermal conductivity is usually desired. However, the laminated structure may also be relied upon to provide some degree of electrical isolation between the electrical devices and the chassis or heat sink. This combination of desired characteristics (i.e., high thermal conductivity and electrical isolation) can make the design and/or manufacture of a suitable laminated structure particularly challenging.

One type of prior art multi-layer laminated structure is commonly referred to as a thermal clad insulated metal substrate. This structure is made up of a circuit layer, a dielectric layer and a base layer. The dielectric layer bonds the circuit layer and the base layer together. The base layer is typically a metal sheet.

One drawback associated with this type of prior art laminated structure described above is that it does not have as high a thermal conductivity as desired, and therefore, the laminate does not support as high a power density as might be desired.

Another drawback is that the base layer is not as good a heat sink as might be desired. This can be alleviated somewhat by bonding or bolting the base of the laminate to another heat sink. However, the thermal conductivity of the resulting structure may still not be as high as desired, and consequently, may not support as high a power density as desired. Moreover, bonding the laminate to a heat sink increases the profile (and volume) of the structure, thereby leaving less volume in the system for mounting electrical devices, which also tends to reduce the power density.

Lastly, the laminate is difficult to manufacture. Consequently, the laminate manufacturer typically sells the laminate only in its final form.

Accordingly, it is an object of the present invention to provide laminated structures for mounting electrical devices and methods of making such structures, one or more embodiments of which overcomes one or more of the above described drawbacks of the prior art.

### SUMMARY

According to a first aspect of the present invention, a multi-layer laminate on which electrical devices may be mounted comprises a printed circuit portion, a first electrically isolating layer, and a substantially rigid base. The printed circuit portion has a first major surface to receive one or more electrical devices to be mounted on the multi-layer laminate. The multi-layer laminate further includes a first adhesive layer disposed between a second major surface of the printed circuit portion and a first surface of the first electrically isolating layer, and a second adhesive layer disposed between a second surface of the first electrically isolating layer and the substantially rigid base. The first adhesive layer and the second adhesive layer each comprise an adhesive that is sufficiently activatable at a first set of processing conditions to at least tack bond the printed circuit portion to the first electrically isolating layer, and sufficiently re-activatable at a second set of processing conditions to bond the first electrically isolating layer to the substantially rigid base.

According to another aspect of the present invention, a multi-layer laminate on which electrical devices may be mounted, comprises: a printed circuit portion, a first electrically isolating layer, and a substantially rigid base. The printed circuit portion has a first major surface to receive one or more electrical devices to be mounted on the multi-layer laminate. The multi-layer laminate further comprises means for bonding a second major surface of the printed circuit portion to a first major surface of the first electrically isolating layer, and bonding a second major surface of the first electrically isolating layer to the substantially rigid base. The said means for bonding is sufficiently activatable at a first set of processing conditions to at least tack bond the second major surface of the printed circuit portion to the first major surface of the first electrically isolating layer, and is sufficiently re-activatable at a second set of processing conditions to bond the second major surface of the first electrically isolating layer to the substantially rigid base.

According to another aspect of the present invention, a method of fabricating a multi-layer laminate comprises: forming a lay-up including a printed circuit portion, a first adhesive layer, a first electrically isolating layer, and a second adhesive layer, where the printed circuit portion has a first major surface to receive one or more electrical devices to be mounted on the multi-layer laminate. The method further comprises exposing the lay-up to first set of processing conditions to activate the first adhesive layer to form at least a tack bond between a second major surface of the printed circuit portion and a first major surface of the first electrically isolating layer, and exposing the lay-up to second set of processing conditions to re-activate the second adhesive layer so as to bond a second major surface of the first electrically isolating layer to a substantially rigid base.

According to another aspect of the present invention, a method of fabricating a multi-layer laminate comprises: forming a lay-up including a printed circuit portion, a first electrically isolating layer, and a substantially rigid base, where the printed circuit portion has a first major surface to receive one or more electrical devices to be mounted on the multi-layer laminate. The method further comprises providing a first adhesive layer between a second major surface of the printed circuit portion and a first major surface of the first electrically isolating layer, and providing a second adhesive layer between a second major surface of the first electrically isolating layer and the substantially rigid base. The first and second adhesive layers each comprise an adhesive sufficiently activatable at a first set of processing conditions to at least tack bond the second major surface of the printed circuit portion to the first major surface of the first electrically isolating layer, and sufficiently re-activatable at a second set of processing conditions to bond the second major surface of the first electrically isolating layer to the substantially rigid base.

One or more embodiments of one or more aspects of the present invention may be used to overcome one or more of the drawbacks associated with the prior art. For example, some embodiments of the present invention employ an adhesive that is activatable at a first set of processing conditions and re-activatable at a second set of processing. By using an adhesive of this type, a lamination process may be split up into at least two separate lamination steps, without a need to add additional adhesive layers. The ability to avoid the need for additional adhesive layers helps achieve a desired thermal conductivity.

In addition, the ability to split a lamination process into two separate lamination processes makes it easier to fabricate a laminate having a “finned” base (i.e., a base/heat sink combination). A “finned” base typically provides better thermal conductivity than a similarly sized base without a heat sink. A “finned” base typically also provides better thermal conductivity than a similarly sized multi-piece base/heat sink structure, all else being equal. Better thermal conductivity helps achieve a desired power density. In addition, a one piece base/heat sink structure may also have a thinner profile than the multi-piece structure, thereby reducing the volume of the base and heat sink, which also helps achieve a desired power density.

Furthermore, the option to split a lamination process into at least two lamination steps, without a need to add additional adhesive layers, may make it practical for a manufacturer to sell portions of a multi-layer laminate, e.g., a laminate less the base. The purchaser may produce the remaining parts (which may be custom designed for the application) and assemble the laminate into its final form.

Other advantages of one or more embodiments of one or more aspects of the multi-layer laminate and method of the present invention will become apparent in view of the following detailed description of preferred embodiments, claims, and accompanying drawings.

However, notwithstanding the potential advantages of one or more embodiments of one more aspects of the present invention, it should be recognized that there is no requirement that every embodiment of the present invention address the shortcomings of the prior art.

### BRIEF DESCRIPTION OF THE DRAWINGS

FIG. 1 is a perspective view of a laminate in accordance with one embodiment of the present invention;

FIG. 2 is a cross-sectional view of the laminate of FIG. 1 taken in the direction of A-A;

FIG. 3 is a cross-sectional view of one embodiment of the first isolation/bond layer of FIG. 2;

FIG. 4 shows one method for fabricating the lay-up portion of the laminate shown in FIG. 2;

FIG. 5 shows one method for fabricating two lay-up portions simultaneously;

FIG. 6 shows one method for attaching the lay-up to the base of FIG. 2;

FIG. 7 is a perspective view of a laminate in accordance with a second embodiment of the present invention; and

FIG. 8 is another perspective view of the laminate of FIG. 7.

### DETAILED DESCRIPTION

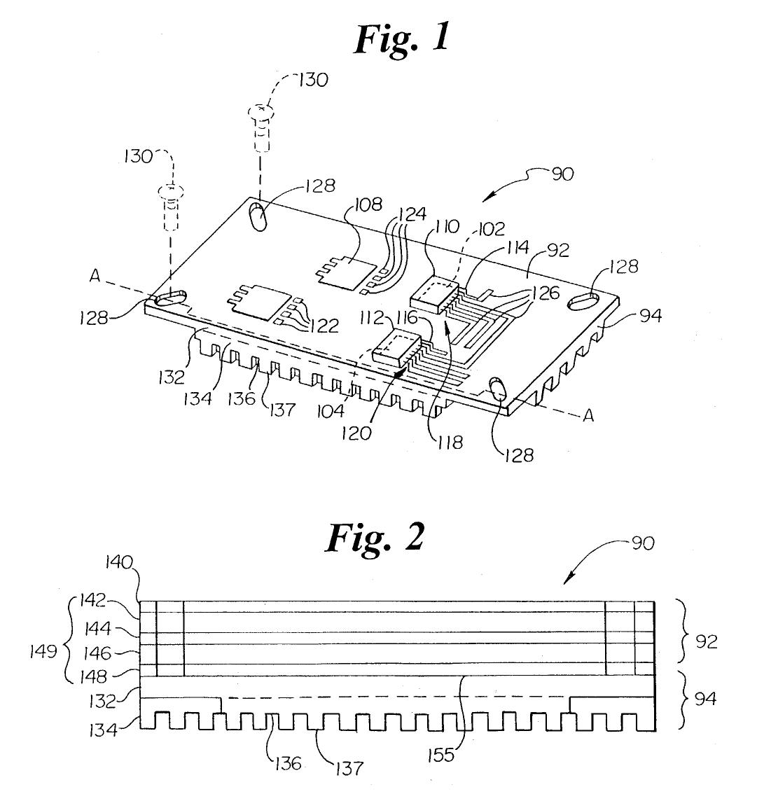

FIG. 1 is a perspective view of a multi-layer laminate 90, in accordance with one embodiment of the present invention. The multi-layer laminate 90 may be used to mount electrical devices and may be attached to a chassis or some other structure (not shown).

The multi-layer laminate 90 includes a printed circuit portion 92 and a base 94. (Note that FIG. 2 shows further details of the layers of the laminate 90.) The printed circuit portion 92 is adapted to receive and electrically connect to one or more electrical devices. This portion 92 has a plurality of areas 102, 104, 106 and 108 on which electrical devices may be mounted. Two electrical devices 110, 112 are shown. One of these devices, i.e., device 110, is mounted on mounting area 102. The other device, i.e., device 112, is mounted on mounting area 104. Each of the mounting areas 102, 104, 106 and 108 includes one or more terminals for electrically connecting to the electrical device to be mounted thereon. For example, mounting area 102 includes terminals 118, which connect to the device 110. Mounting area 104 includes terminals 120, which are electrically connected to the device 112. Likewise, mounting areas 106, 108 include terminals 122, 124, respectively, for electrically connecting to electrical devices that are to be mounted thereon. The laminate 90 also includes a plurality of electrically conductive traces, for example as indicated at 126, to form one or more electric circuits.

The base 94 shown in FIG. 1 can be viewed as a one piece, integrally formed, combination base/“finned” heat sink. The base 94 has a first portion 132 and a second portion 134. One or both of these portions are rigid (i.e., relative to the printed circuit portion 92, which is formed of flexible components) so as to provide support for the printed circuit portion 92. The first portion 132 is substantially planar on its major outer surface 155 (FIG. 2). The second portion 134 has a major outer surface 136 and a plurality of fins 137 extending therefrom. The fins, which are shown as rectangular but which may have any size and shape, improve thermal conductivity between the base 94 and the ambient air. The base 94 is preferably metal so as to provide high thermal conductivity.

It should be recognized that because the base 94 is a single piece, it may provide better thermal conductivity than a similarly sized and shaped multi-piece structure, e.g., base/adhesive/heat sink, all else being equal. In addition, the one piece structure may have a thinner profile than the multi-piece structure (because the multi-piece structure has an additional joint and an accompanying adhesive layer), thereby reducing the volume needed for a base and heat sink. This in turn may make it possible to deliver greater performance (e.g., power) without increasing the size of the overall system, all else being equal.

As stated above, the laminate 90 may be attached to a chassis or some other structure (not shown). Consequently, slots 128 are provided in this embodiment to receive bolts (e.g., bolts 130, shown in phantom) to attach the laminate 90 to such chassis or other structure (not shown).

FIG. 2 is a cross-sectional view of the laminate 90 taken along the direction A-A (FIG. 1). The printed circuit portion 92 of the laminate includes a solder mask 140 and a plurality of layers, including a first electrically conductive layer 142, a first isolation/bond layer 144, a second electrically conductive layer 146 and a second isolation/bond layer 148. Hereafter, the solder mask 140 and the layers 142-148 are collectively referred to as lay-up 149. The solder mask 140 may comprise any suitable material(s), for example, but not limited to XV601T SPRAY IMAGEFLEX, manufactured by Coates Circuit Products, a division of Coates Screen, of St. Charles, Ill.; and PYRALUX PC2000, with a UL-94 VTM-0 rating, which is manufactured by Dupont. The SPRAY IMAGEFLEX material is a thermal hardening, liquid, photo imageable flexible solder mask that dries by evaporation to form an aqueousprocessable film with a semi-gloss or semi-matte finish. Some embodiments employ the SPRAY IMAGEFLEX material to form a solder mask 140 having a thickness of about 0.002 inches to about 0.003 inches.

The first and second electrically conductive layers 142, 146 may, comprise copper, copper foil, or any other suitably conductive material(s). The first and second electrically conductive layers 142, 146 interconnect to the electrical devices mounted on the laminate and have patterning to form traces and one or more electrical circuits. These layers 142, 146 may, comprise copper, copper foil, or any other suitably conductive material(s). In this embodiment, the first and second isolation/bond layers 144, 148 are substantially identical to one another, although this is not required for all embodiments of all aspects of the present invention.

The thickness of the lay-up 149 is preferable less than or equal to about 0.125 inches. However, in this embodiment, the thickness of the lay-up 149 is for example, in the range of from about 0.013 inches to about 0.015 inches. The thickness of the base 94, less the height of any fins, is preferable greater than or equal to about 0.03 inches and more preferably greater than or equal to about 0.04 inches. In some embodiments, the fins extend about 0.06 inches, but the fins are not limited to such.

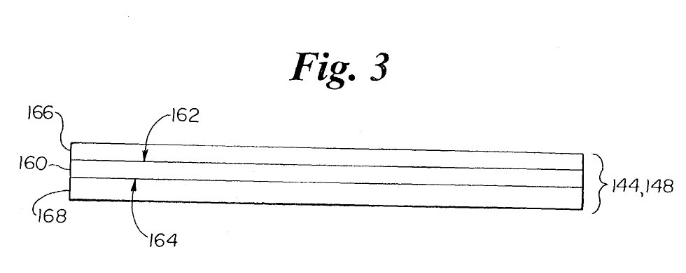

FIG. 3 shows a cross section view of one embodiment of the isolation/bond layers 144, 148. This embodiment includes three layers: (1) a flexible substrate layer 160 having a first major surface 162 and a second major surface 164, (2) a first adhesive layer 166 on the first major surface 162 of the substrate layer 160, and (3) a second adhesive layer 168 on the second major surface 164 of the substrate layer 160.

The isolation/bond layers 144, 148 may be formed in any manner that is currently known, or later becomes known for performing the functions of these layers as described herein. In some embodiments, the first and/or second isolation/bond layers 144, 148 are manufactured in accordance with one or more of the methods and materials set forth in U.S. Pat. Nos. 6,015,607 and/or 6,208,031, each of which is incorporated herein by reference. In such embodiments, the flexible substrate layer 160 may comprise a flexible film (for example comprising a polyimide, polyester and/or a polyetherimide) and the adhesive layers 166, 168 may comprise a polyetherimide adhesive, for example Ultem, and siloxane polyetherimide copolymer, for example Siltem (both of which are trademarks of G.E. Plastics). Hereafter, the term “polyetherimide” includes polyetherimide adhesives, for example Ultem, and siloxane polyetherimide copolymers, for example Siltem, unless stated otherwise.

In some embodiments, the isolation/bond layers 144, 148 comprise TPI-130, manufactured by Fraivillig Technologies of Marlboro, Mass., which is a multi-layer product having (1) a flexible substrate layer, (2) a first adhesive layer on a first major surface of the flexible substrate layer, and (3) a second adhesive layer on a second major surface of the flexible substrate layer.

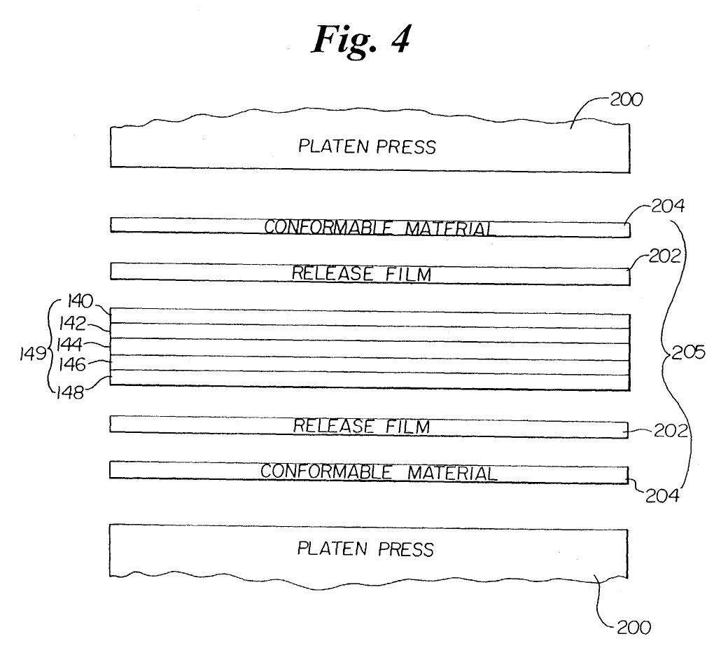

In a preferred embodiment, (further described hereinafter with respect to FIG. 4) the first and second adhesive layers 166, 168 each comprise an adhesive that is activatable at a first set of processing conditions and re-activatable at a second set of processing conditions. A set of processing conditions may include, for example, but is not limited to: one or more temperatures, one or more pressures, and the time duration(s) that the temperature(s) and pressure(s) are applied. The second set of processing conditions differs from the first set of processing conditions in at least one respect. For example, the second set of processing conditions may differ from the first set of processing conditions in regard to the temperature(s), the pressure(s), the duration for which the temperature(s) are applied, and/or the duration for which the pressure(s) are applied.

One method for fabricating the laminate 90 includes the following two steps: (1) fabricating the lay-up 149 portion of the laminate 90 (i.e., the portion of the laminate 90 that comprises the solder mask 140 and layers 142-148, and (2) bonding the lay-up 149 to the base 94. This method facilitates fabrication of laminates having bases that are non-planar, such as for example, laminate 90 which has a “finned” base 94.

FIG. 4 illustrates one method for fabricating the lay-up 149 (i.e., the solder mask 140 and layers 142-148) portion of the laminate 90. In this method, a multi-opening platen press 200 is used. Each platen 200 includes one or more heating elements (not shown) that heats the platen. The platen in turn transmits heat to a workpiece in the platen press. The platens 200 are initially heated to about 180 degrees centigrade (deg C.).

The solder mask 140 and the layers 142-148 which form the lay-up are assembled. The lay-up 149 is sandwiched between two release films 202 and two sheets of conformable material 204 to form a stack-up 205. The conformable material 204 is employed to help ensure that pressure will be sufficiently applied across the major outer surface of the printed circuit portion. That is, even if the major outer surface of the printed circuit portion is substantially planar, there may be some areas that are slightly raised compared to other areas, e.g., the surface areas over conductive traces may be slightly raised compared to surface areas without conductive traces.

The stack-up 205 is placed into the platen press 200. The initial pressure on the stack-up 205 is due merely to the weight of the platen. Pressure is then applied to the portion of the platen 200 that contacts the stack-up 205. This pressure is in turn delivered to the stack-up 205. The magnitude of the pressure may be, for example, in the range of from about 1 pound per square inch (psi) to about 10 psi. These temperature and pressure conditions are maintained for a time duration in the range of from about 2 minutes to about 4 minutes, in order to help eliminate (or at least reduce) residual moisture from the lay-up 149.

The pressure and/or the temperature is then increased to provide conditions (e.g., temperature, pressure, time duration) suitable to activate the adhesive layers 162, 164 to a degree sufficient to form at least a tack-bond between the electrically conductive layers 142, 146 and the isolation/bond layers 144, 148, yet leave enough re-activity in the second isolation/bond layer 148 to allow the layer 148 to be bonded to another surface at a future time. For example, in this embodiment, the temperature is maintained at 180 deg C. and the magnitude of the applied pressure is increased to greater than or equal to about 500 psi. These conditions are maintained for about 1 minute. The press is opened while still at about 180 deg C. and the stack-up 205 is removed while in a ‘hot state’. If desired, the edge of the lay-up 149 may be checked to verify the existence of a tack-bond between the electrically conductive layers 142, 146 and the isolation/bond layers 144, 148. However, it is desirable to prevent air entrapment and/or voids in the laminate 90. The lay-up may be removed from the plate/lay-up assembly using a steel-rule or equivalent, for example.

The conformable material 204 shown in FIG. 4 may, for example, be pacoform or rubber. The release film 202 material may, for example, be skived PTE (having a thickness of about 1 mil) or teflon coated glass (having a thickness of about 3 mils). The release film 202 may be a separate film, as shown, or alternatively, may be incorporated into the conformable material 204.

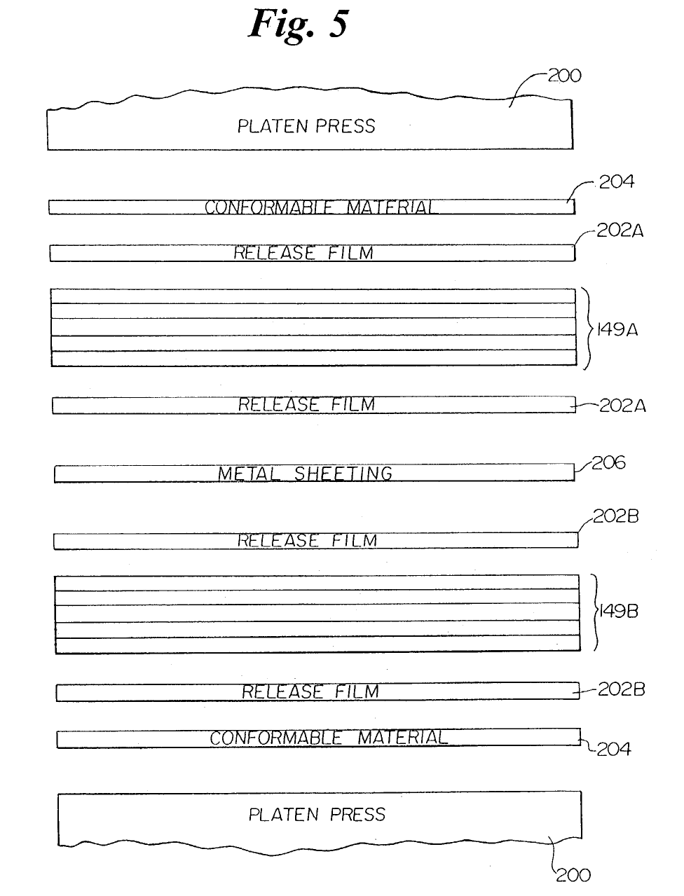

FIG. 5 shows one arrangement that may be used to fabricate two lay-ups 149A, 149B simultaneously. The arrangement and process of fabrication is substantially the same as that described above with respect to FIG. 4, except that there are two lay-ups 149A, 149B, two pairs of release films 202A, 202B, and a metal sheeting 206 interposed between the two lay-ups. The thickness of the metal sheeting 206 is, for example, between 0.02 and 0.03 inches.

In some embodiments, more than two lay-ups (e.g., 4-6) are fabricated simultaneously. This can be accomplished by adding additional lay-ups and metal sheeting to the arrangement.

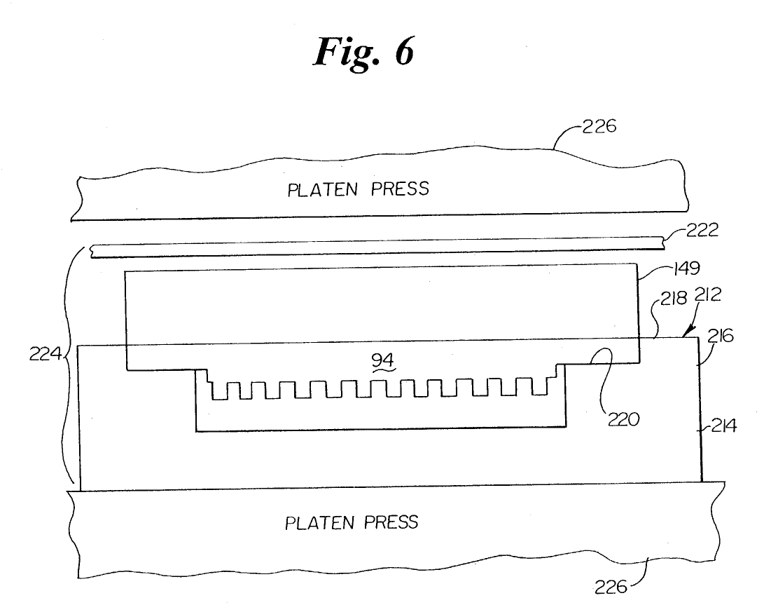

FIG. 6 illustrates one method for attaching the lay-up portion 149 to the base 94. In this method, the base 94 is positioned in a fixture 212. The fixture 212 has a foundation portion 214 and side walls 216. The side walls 216 have a major upper surface 218 and abutments 220. The abutments 220 are recessed from the major upper surface 218 such that upon placing the base 94 in the fixture 212, the major upper surface 218 is flush with the major outer surface of the base 94. The foundation portion 214 is recessed to provide clearance between the fixture 212 and the base 94.

After the base 94 is positioned in the fixture 212, the lay-up 149 is positioned above the base 94 and a release film 222 is positioned over the lay-up 149. The assembly 224 (i.e., fixture 212, base 94, lay-up 149, release film 222) is placed into a platen press 226. The platens 226 are heated to about 300 degrees centigrade (deg C.). The force on the assembly 224 is initially only that of the weight of the platen 226. The initial temperature and force conditions are maintained for a time duration of about 2 to 3 seconds. A force of about 1000 pounds is then applied to the platen 226, which in turn delivers the force to the assembly 224. This force is intended to help drive trapped air out of the assembly 224. This force may be applied for 15 seconds to 30 seconds.

The force and/or the temperature is then increased to provide conditions (e.g., temperature, pressure, time duration) to re-activate the adhesive layer 148 to a degree sufficient to form a bond between the lay-up 149 and the base 94. For example, in this embodiment, the temperature is maintained at 300 deg C. and the applied force is increased to greater than or equal to about 4000 pounds. These conditions are maintained for about 30 seconds. The assembly 224 is then removed from the platen press 226. The lay-up/base are then removed from the fixture 214. In some embodiments, the fixture 214 includes an ejection mechanism (not shown) to eject the base 94 from the fixture 214.

In some embodiments, the base 94 undergoes surface preparation prior to attaching the lay-up 149. For example, in some embodiments, a coating is applied to the major outer surface of the base 94 in order to fill any recesses in the surface of the outer major surface, and thereby provide a more uniform surface for bonding to the lay-up 159. The coating may comprise a polyamide material in liquid etch form, although it is not limited to such.

Although FIG. 6 shows only one lay-up 149 and only one base 94, it should be recognized that some embodiments may attach multiple lay-ups to multiple bases simultaneously.

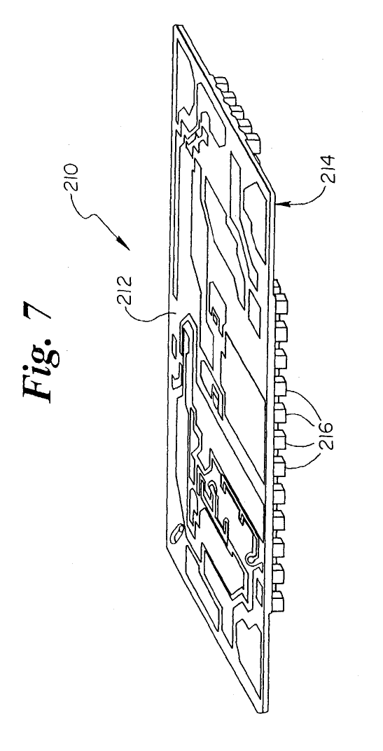

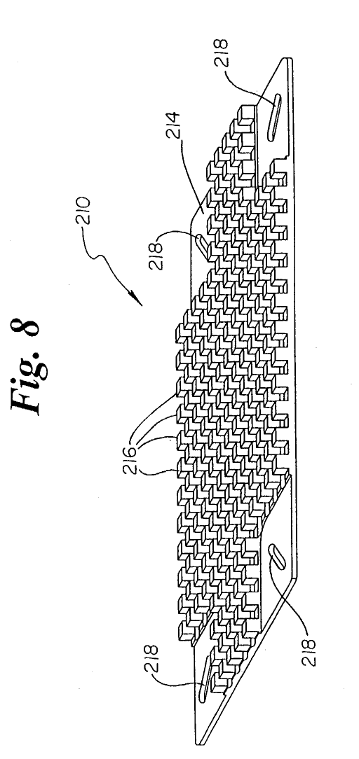

FIG. 7 is a perspective view of a laminate 210 in accordance with a second embodiment of the present invention. The laminate 210 has a printed circuit portion 212 and a base 214. The printed circuit portion 210 has substantially the same types of layers as the printed circuit portion 92 of the laminate 90 (FIGS. 1,2). The base 214 has fins 216 and is substantially the same as the base 94 of the laminate 90 (FIGS. 1,2).

FIG. 8 is another perspective view of the laminate 210. This view shows further details of the base 214 employed in this embodiment. As with the base 94 of the laminate 90 (FIG. 1), the fins 216 which are shown as rectangular, may have any size and shape. The laminate 210 is shown with slots 218 to receive bolts (not shown) to attach the laminate to a chassis or other structure (not shown), however, as stated above, slots need not be employed in all embodiments.

Although the embodiments of the laminates shown above each include two electrically conductive layers that form a printed circuit to electrically connect to the electrical devices to be mounted on the laminates, the present invention is not limited to such. For example, in some embodiments, a printed circuit with only one electrically conductive layer may be needed. In some other embodiments, the printed circuit may require more than two electrically conductive layers.

Moreover, it should also be recognized that there are many types of electrical devices. For example, some types of electrical devices are referred to as discrete devices. Exemplary types of electrical devices include discrete devices, integrated circuit devices, and hybrid devices. Exemplary discrete devices include discrete resistors, capacitors, inductors as well as discrete semiconductor devices (e.g., diodes, transistors). Integrated circuits are commonly formed from semiconductors. Although some embodiments of the present invention may provide characteristics that are particularly advantageous for “high power” systems or applications, for example, as found in some power supply systems or applications, the present invention is not limited to any particular type or types of electrical devices or any particular application or applications.

Furthermore, electrical devices can be packaged in many different ways. The present invention is not limited to any particular type of package. Thus, for example, although the laminate 90 is shown adapted to receive surface-mount type electrical devices (e.g., 102, 104) with “gull-wing” type leads (e.g., 114, 116), the present invention is not limited to such. For example, other embodiments may be adapted to receive other types of devices, including but not limited to, for example, other types of surface-mount devices with other types of terminals (e.g., pin grid arrays and/or ball arrays) and non surface-mount devices (e.g., dual-in-line packages) or combinations thereof. Consequently, although the terminals 118, 120 are shown as being in the form of pads, other embodiments may employ other types of structures for electrically connecting to the electrical devices, for example, but not limited to plated holes.

Although the laminate 90 has slots 128 for bolts 130 that attach the laminate 90 to a housing or other structure (not shown), slots are not required for the present invention. For example, some embodiments may employ some other type of fastener or fastening arrangement (e.g., clamp(s)) to attach the laminate 90 to a housing or other structure. Yet other embodiments may employ adhesive(s). Still further embodiments may employ combinations of two or more of these structures. In some other embodiments, the base may not attach to a housing or other structure.

As stated above, the base is not required to be metal. For example, some embodiments may employ a base that is a ceramic material and/or a ferromagnetic rather than metal. In some other embodiments, the base may comprise a combination of ceramic, ferromagnetic and metal materials.

Moreover, although one or both of the portions of the base 94 are rigid (i.e., relative to the printed circuit portion 92, which is formed of flexible components) this is not required. For example, some embodiments may employ a base that is substantially rigid (i.e., relative to a printed circuit portion) but not rigid (i.e., relative to the printed circuit portion). As used herein, and except where otherwise stated, the phrase “substantially rigid” implies at least substantially rigid, so as not to preclude rigid.

In addition, although the base 94 shown in FIGS. 1 and 2 has one major outer surface 155 that is substantially planar and one major outer surface having fins extending therefrom, the present invention is not limited to such. For example, in some embodiments, both of the major outer surfaces of the base may be substantially planar. In some other embodiments, the base does not have a major outer surface that is substantially planar, but rather has one or more major outer surfaces that are curved, spherical, piecewise-planar, irregular and/or combinations thereof In some embodiments, the base has only one major outer surface, for example where the base is spherical. A base may be fabricated in one piece, or alternatively, fabricated in separate pieces and then joined together.

Although the base 94 and the printed circuit portion 92 are shown substantially coextensive with one another in FIGS. 1, 2, this is not required for the present invention. For example, in some other embodiments, the surface area of either the printed circuit portion 92 or the base 94 may be greater than the surface area of the other.

Furthermore, although the method disclosed above for forming the lay-up employs a platen press and the platens have heating elements, the present invention is not limited to methods that employ a platen press and/or platens with heating elements.

It should also be understood that the processing conditions used in any given situation to activate and re-activate an adhesive layer are not limited to the processing conditions described above. Thus, for example, some embodiments will use processing conditions that are different than the processing conditions described above. Note that, except where otherwise stated, the phrase a “printed circuit portion” is open ended, meaning that it includes, but is not limited to, at least one electrically conductive layer that provides at least a portion of a printed circuit. For example, a printed circuit portion may include layers other than electrically conductive layers.

As used herein, the term “layer” implies a position in the cross section (profile) of the laminate. However, a layer may be continuous or discontinuous. For example, a conductive layer may be an etched printed circuit layer. Moreover, a layer may or may not be planar or even substantially planar. For example, a conformal layer on a non-planar surface will be non-planar.

As used herein, the term “metal”, if used as an adjective to describe a structure, means that the majority of a structure is composed of one or more metals. However, the composition of a “metal” structure may be homogeneous (uniform throughout) or non-homogeneous (non-uniform throughout).

As used herein, except where otherwise stated, the phrase “bond” implies relatively firm adhesion, which at least after some elapsed time and/or cooling, is sufficient for the intended use of the laminate. However, the phrase “tack bond” implies relatively weak adhesion that is insufficient for the intended use of the laminate.

Note that, except where otherwise stated, phrases such as, for example, “connected to” mean “connected directly to” or “connected indirectly to”.

Also note that, except where otherwise stated, terms such as, for example, “comprises”, “has”, “includes”, and all forms thereof, are considered open-ended, so as not to preclude additional elements and/or features.

While there have been shown and described various embodiments, it will be understood by those skilled in the art that the present invention is not limited to such embodiments, which have been presented by way of example only, and that various changes and modifications may be made without departing from the spirit and scope of the invention. Accordingly, the invention is limited only by the appended claims and equivalents thereto.

What is claimed is:

1. A multi-layer laminate on which electrical devices may be mounted, the multi-layer laminate comprising:
a printed circuit portion having a first major surface to receive one or more electrical devices to be mounted on the multi-layer laminate, the printed circuit portion further having a second major surface and a first electrically conductive layer having one or more conductive traces to be electrically connected to one or more of the electrical devices to be mounted on the multi-layer laminate;
a substantially rigid base having a first major surface;
a first electrically isolating layer having a first major surface and a second major surface;
a first adhesive layer disposed between the second major surface of the printed circuit portion and the first major surface of the first electrically isolating layer; and
a second adhesive layer disposed between the second major surface of the first electrically isolating layer and the first major surface of the substantially rigid base;
wherein the first adhesive layer and the second adhesive layer each comprise an adhesive that is sufficiently activatable at a first set of processing conditions to at least tack bond the second major surface of the printed circuit portion to the first major surface of the first electrically isolating layer, and sufficiently re-activatable at a second set of processing conditions to bond the second major surface of the first electrically isolating layer to the first major surface of the substantially rigidbase.

2. The multi-layer laminate of claim 1 wherein the substantially rigid base comprises a rigid base.

3. The multi-layer laminate of claim 1 wherein the substantially rigid base comprises a rigid, metal base.

4. The multi-layer laminate of claim 2 wherein the first electrically isolating layer comprises a flexible film.

5. The multi-layer laminate of claim 4 wherein the first adhesive layer comprises an adhesive coating on the first major surface of the first electrically isolating layer and the second adhesive layer comprises an adhesive coating formed on the second major surface of the first electrically isolating layer.

6. The multi-layer laminate of claim 4 wherein the flexible film comprises a polyimide film, a polyester film, or a polyetherimide film.

7. The multi-layer laminate of claim 4 wherein the flexible film has a thickness that is less than or equal to about 0.001 inches.

8. The multi-layer laminate of claim 7 wherein the adhesive coatings have a thickness of less than about 0.001 inches.

9. The multi-layer laminate of claim 3 wherein the first major surface of the rigid, metal base is substantially planar.

10. The multi-layer laminate of claim 3 wherein the rigid, metal base has a thickness that is greater than or equal to about 0.03 inches.

11. The multi-layer laminate of claim 3 wherein the rigid, metal base is adapted to be attached to a structure to support the multi-layer laminate.

12. The multi-layer laminate of claim 3 wherein the rigid, metal base has a second major surface and a plurality of fins extending therefrom.

13. The multi-layer laminate of claim 12 wherein the further electrically conducting layer has a first major surface and a second major surface and the multi-layer laminate further comprises:
a second electrically conducting layer having a first major surface;
a second electrically isolating layer having a first major surface and a second major surface;
a third adhesive layer disposed between the first major surface of the first electrically conductive layer and the first major surface of the second electrically isolating layer;
a fourth adhesive layer disposed between the second major surface of the second electrically isolating layer and the first major surface of the second electrically conducting layer; and
wherein the third adhesive layer and the fourth adhesive layer each comprise an adhesive that is sufficiently activatable at the first set of processing conditions to at least tack bond the first major surface of the first electrically conductive layer to the first major surface of the second electrically isolating layer, and to at least tack bond the second major surface of the second electrically isolating layer to the first major surface of the second electrically conductive layer.

14. The multi-layer laminate of claim 13 wherein the second electrically conducting layer has a second major surface, and a solder mask is disposed thereon.

15. A multi-layer laminate on which electrical devices may be mounted, the multi-layer laminate comprising:
a printed circuit portion having a first major surface to receive one or more electrical devices to be mounted on the multi-layer laminate, the printed circuit portion further having a second major surface and a first electrically conductive layer having one or more conductive traces to be electrically connected to one or more of the electrical devices to be mounted on the multi-layer laminate;
a substantially rigid base having a first major surface;
a first electrically isolating layer having a first major surface and a second major surface; and
means for bonding the first major surface of the first electrically conductive layer to the second major surface of the printed circuit portion, and bonding the second major surface of the first electrically isolating layer to the first major surface of the substantially rigid base, said means for bonding being sufficiently activatable at a first set of processing conditions to at least tack bond the second major surface of the printed circuit portion to the first major surface of the first electrically isolating layer, and sufficiently re-activatable at a second set of processing conditions to bond the second major surface of the first electrically isolating layer to the first major surface of the substantially rigid base.

16. The multi-layer laminate of claim 15 wherein the substantially rigid base comprises a rigid, metal base.

17. The multi-layer laminate of claim 16 wherein the means for bonding is defined by an adhesive sufficiently activatable at the first processing conditions to at least tack bond the second major surface of the printed circuit portion to the first major surface of the first electrically isolating layer, and sufficiently re-activatable at a second temperature and pressure to bond the second major surface of the first electrically isolating layer to the first major surface of the rigid base.

18. A method of fabricating a multi-layer laminate on which electrical devices may be mounted, the method comprising:
forming a lay-up including a printed circuit portion, a first adhesive layer, a first electrically isolating layer, and a second adhesive layer, where the printed circuit portion has a first major surface to receive one or more electrical devices to be mounted on the multi-layer laminate, the printed circuit portion further has a second major surface and a first electrically conductive layer having one or more conductive traces to be electrically connected to one or more of the electrical devices to be mounted on the multi-layer laminate;
exposing the lay-up to a first set of processing conditions to activate the first adhesive layer to form at least a tack bond between the second major surface of the printed circuit portion and a first major surface of the first electrically isolating layer; and
exposing the lay-up to a second set of processing conditions to re-activate the second adhesive layer so as to bond the second major surface of the first electrically isolating layer to a first major surface of a substantially rigid base.

19. The method of claim 18 wherein the substantially rigid base comprises a rigid, metal base.

20. The method of claim 19 further comprising adding the rigid, metal base to the lay-up only after exposing the lay-up to the first set of processing conditions.

21. The method of claim 19 further comprising including the rigid, metal base in the lay-up prior to exposing the lay-up to the first set of processing conditions.

22. The method of claim 19 wherein the first set of processing conditions comprises a temperature of about 180 degrees centigrade.

23. The method of claim 19 wherein the first set of processing conditions comprises a pressure greater than or equal to about 500 psi, and wherein the second set of processing conditions comprises a force greater than about 4000 pounds.

24. The method of claim 19 wherein the first set of processing conditions comprises a temperature equal to about 180 deg C., and wherein the second set of processing conditions comprises a temperature equal to about 300 deg C.

25. The method of claim 23 wherein the first set of processing conditions further comprises a temperature equal to about 180 deg C., and wherein the second set of processing conditions further comprises a temperature equal to about 300 deg C.

26. A method of fabricating a multi-layer laminate on which electrical devices may be mounted, the method comprising:
forming a lay-up including a printed circuit portion, a first electrically isolating layer, and a substantially rigid base, where the printed circuit portion has a first major surface to receive one or more electrical devices to be mounted on the multi-layer laminate, the printed circuit portion further has a second major surface and a first electrically conductive layer having one or more conductive traces to be electrically connected to one or more of the electrical devices to be mounted on the multi-layer laminate;
providing a first adhesive layer between the second major surface of the printed circuit layer and a first major surface of the first electrically isolating layer; and
providing a second adhesive layer between the second major surface of the first electrically isolating layer and a first major surface of the substantially rigid base;
wherein the first and second adhesive layers each comprise an adhesive sufficiently activatable at a first set of processing conditions to at least tack bond the second major surface of the printed circuit portion to the first major surface of the first electrically isolating layer, and sufficiently re-activatable at a second set of processing conditions to bond the second major surface of the first electrically isolating layer to the first major surface of the substantially rigid base.

27. The method of claim 26 wherein the substantially rigid base comprises a rigid, metal base.

28. A multi-layer laminate fabricated in accordance with the method of claim 20.
